(19) United States
(12) Patent Application Publication
(10) Pub. No.: US 2025/0318407 A1
(43) Pub. Date: Oct. 9, 2025

(54) DISPLAY DEVICE AND METHOD FOR PROVIDING THE DISPLAY DEVICE

(71) Applicant: Samsung Display Co., Ltd., Yongin-si (KR)

(72) Inventor: GWANGTAEK LEE, Yongin-si (KR)

(21) Appl. No.: 19/027,345

(22) Filed: Jan. 17, 2025

(30) Foreign Application Priority Data
Apr. 4, 2024 (KR) 10-2024-0046080

(51) Int. Cl. H10K 59/80; H10K 59/12

(52) U.S. Cl. CPC H10K 59/873; H10K 59/1201

(57) ABSTRACT

A display device includes a display panel including a display surface, a pattern glass including a first non-patterned portion, a patterned portion and a second non-patterned portion which are disposed on the display panel and arranged in a first direction, and a first filling resin filling a first groove defined in an upper surface of the patterned portion and a second filling resin filling a second groove defined in a lower surface of the patterned portion. At least one of an upper surface of the first filling resin or a lower surface of the second filling resin may protrude outward from the pattern glass, and the protruding upper surface of the first filling resin, or the protruding lower surface of the second filling resin may include an inclined surface.

This U.S. non-provisional patent application claims priority to Korean Patent Application No. 10-2024-0046080, filed on Apr. 4, 2024, and all the benefits accruing therefrom under 35 U.S.C. § 119, the entire contents of which are hereby incorporated by reference.

### BACKGROUND

### (1) Field

The present disclosure herein relates to a display device and a method for manufacturing (or providing) the display device.

### (2) Description of the Related Art

An electronic device provides information to users by displaying various images on a display screen. Generally, the electronic device displays information within a dedicated screen.

Flexible electronic devices including a foldable flexible display panel are being developed. Unlike a rigid electronic device, flexible electronic devices may be foldable, rollable, or bendable. Flexible electronic devices deformable into various shapes may be portable regardless of a typical display screen size, thereby improving user convenience.

An electronic device includes a display panel, and a glass disposed on the display panel to protect the display panel. A plurality of patterns may be defined on the glass so as to ensure the flexibility of a flexible electronic device.

### SUMMARY

The present disclosure provides a display device with improved surface quality and a method for manufacturing the display device.

An embodiment of the invention provides a display device including: a display panel including a display surface, a pattern glass including a first non-patterned portion, a patterned portion, and a second non-patterned portion which are disposed on the display panel and arranged in a first direction, and a first filling resin filling a first groove defined in an upper surface of the patterned portion, and a second filling resin filling a second groove defined in a lower surface of the patterned portion, where at least one of an upper surface of the first filling resin or a lower surface of the second filling resin protrudes outward from the pattern glass to define a protruding surface, and the protruding upper surface of the first filling resin, or the protruding lower surface of the second filling resin includes an inclined surface.

In an embodiment of the invention, a method for manufacturing a display device includes: providing a pattern glass including a first non-patterned portion, a patterned portion, and a second non-patterned portion which are arranged in a first direction, providing a plurality of guide adhesive layers on an upper surface and a lower surface of the first non-patterned portion, and an upper surface and a lower surface of the second non-patterned portion, fixing a plurality of release films to an upper part and a lower part of the pattern glass through the guide adhesive layers, filling, with a resin, a filling space defined by the pattern glass, the guide adhesive layers, and the release films, and providing the pattern glass on a display panel, where inner side surfaces, of the guide adhesive layers, facing each other in the first direction each include an inclined surface.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of an electronic device according to an embodiment of the invention;

FIGS. 2A and 2B are views illustrating a state in which the electronic device illustrated in FIG. 1 is folded;

FIG. 3 is an exploded perspective view of an electronic device according to an embodiment of the invention;

FIG. 4 is a cross-sectional view taken along line I-I′ illustrated in FIG. 3;

FIG. 5 exemplarily illustrates a cross-sectional view of a display panel illustrated in FIG. 3;

FIG. 6 is a plan view of the display panel illustrated in FIG. 5;

FIG. 7A is an enlarged cross-sectional view corresponding to the first region A1 illustrated in FIG. 4;

FIGS. 7B to 7D are enlarged cross-sectional views of a display device according to an embodiment of the invention;

FIG. 8 is a plan view of a pattern glass illustrated in FIG. 7A;

FIG. 9 is an enlarged cross-sectional view taken along line II-II′ illustrated in FIG. 8;

FIG. 10A is a cross-sectional view illustrating a state in which a display device according to Comparative Example is folded;

FIG. 10B is a cross-sectional view illustrating a state in which the display device illustrated in FIG. 7A is folded; and

FIGS. 11A to 11C are enlarged cross-sectional views for describing a method for manufacturing (or providing) a first filling resin and a second filling resin illustrated in

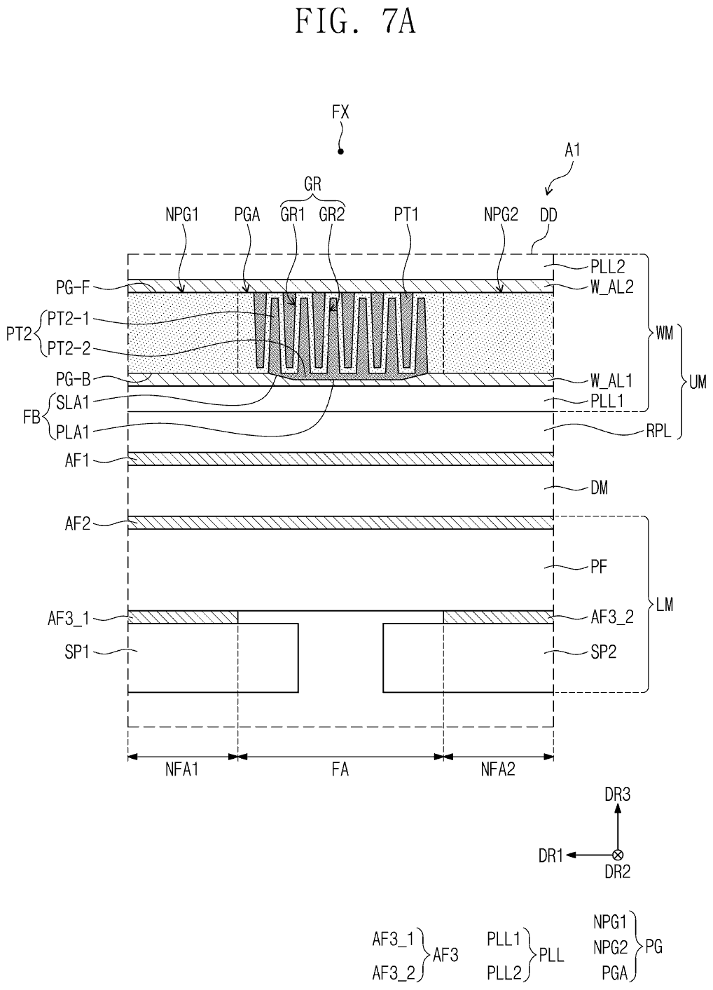

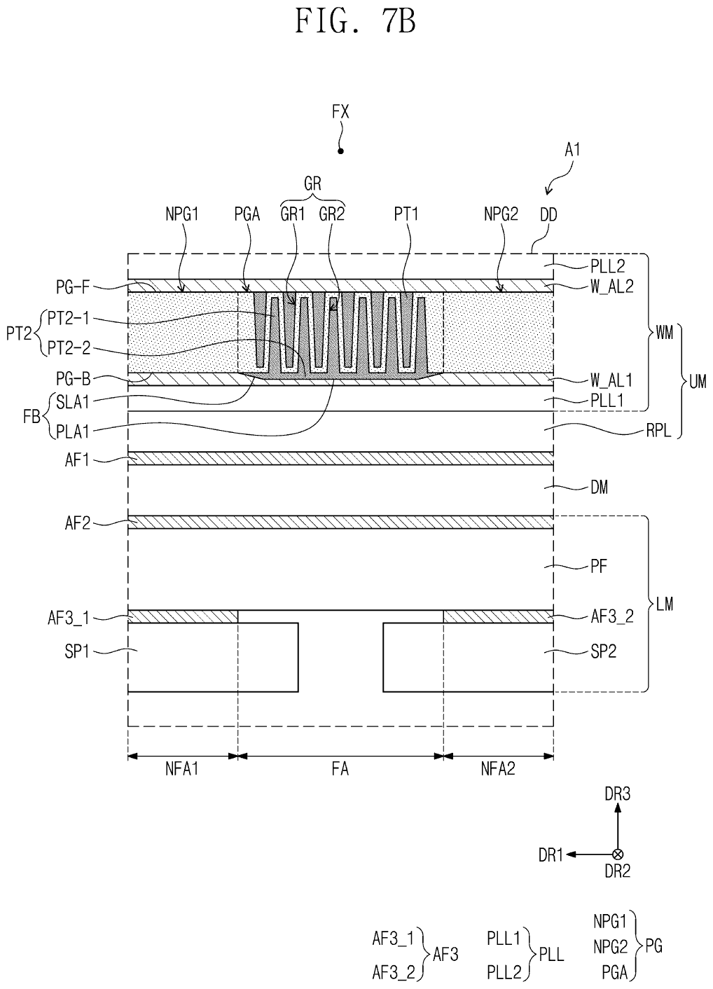

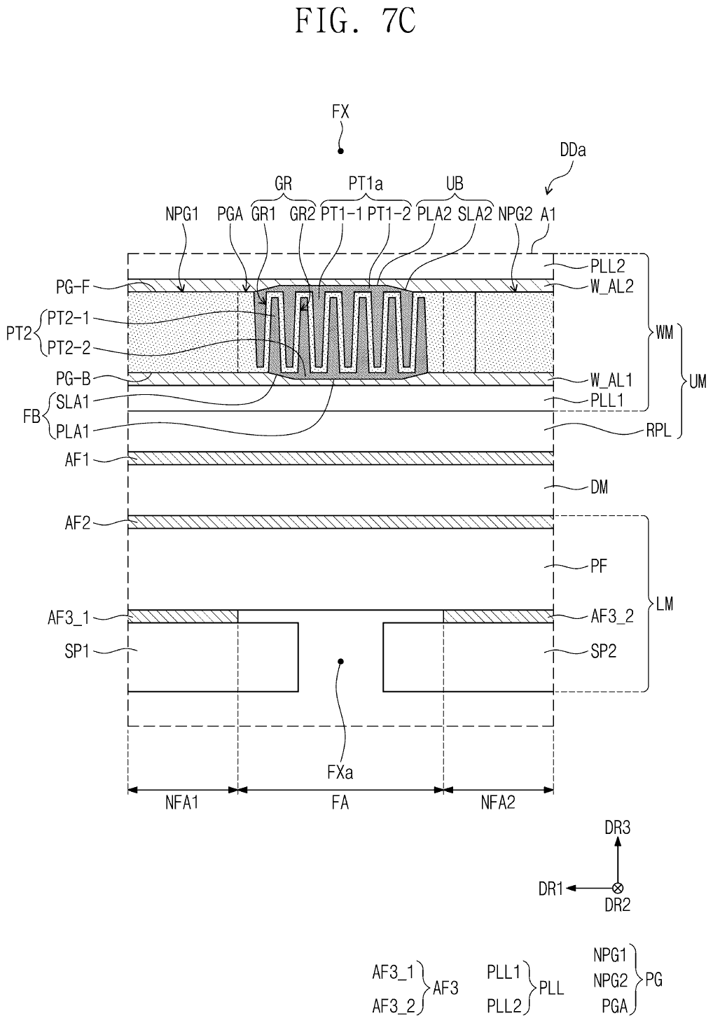

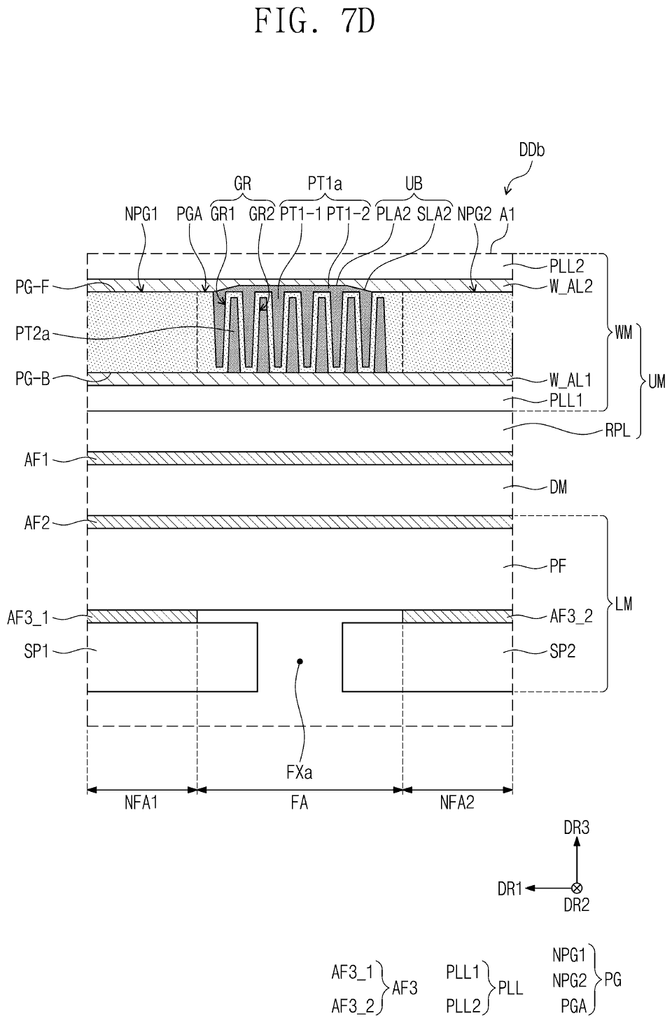

FIG. 7C.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when an element (or region, layer, portion, or the like) is referred to as being related to another element such as being “on”, “connected to” or “coupled to” another element, it may be directly disposed/connected/coupled to another element, or intervening elements may be disposed therebetween. In contrast, when an element (or region, layer, portion, or the like) is referred to as being related to another element such as being “directly on”, “directly connected to” or “directly coupled to” another element, no intervening element is therebetween.

Like reference numerals or symbols refer to like elements throughout. Within the Figures and the text of the disclosure, a reference number indicating a singular form of an element may also be used to reference a plurality of the singular element.

Also, in the drawings, the thicknesses, the ratios, and the dimensions of the elements are exaggerated for effective description of the technical contents.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” The term “and/or” includes all of one or more combinations defined by the associated elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the invention. As used herein, expressions such as (1-1)-th, (1-2)-th, (2-1)-th, (2-2)-th, (3_1)-th, (3_2)-th, etc. may be used to indicate a first-first element, a first-second element, a second-first element, a second-second element, a third-first element, a third-second element, etc., without being limited thereto.

Also, the terms such as “below”, “lower”, “above”, “upper” and the like, may be used for the description to describe one element's relationship to another element illustrated in the figures. It will be understood that the terms have a relative concept and are described on the basis of the orientation depicted in the figures.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the invention will be described with reference to the accompanying drawings.

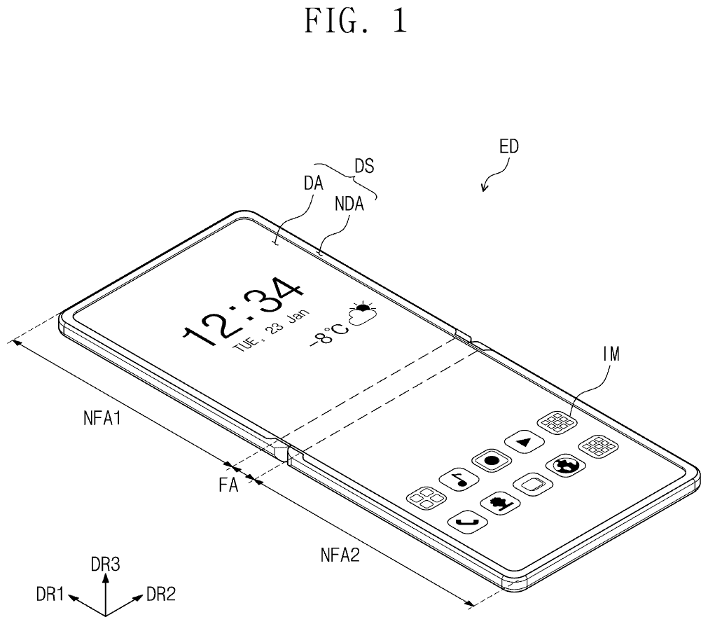

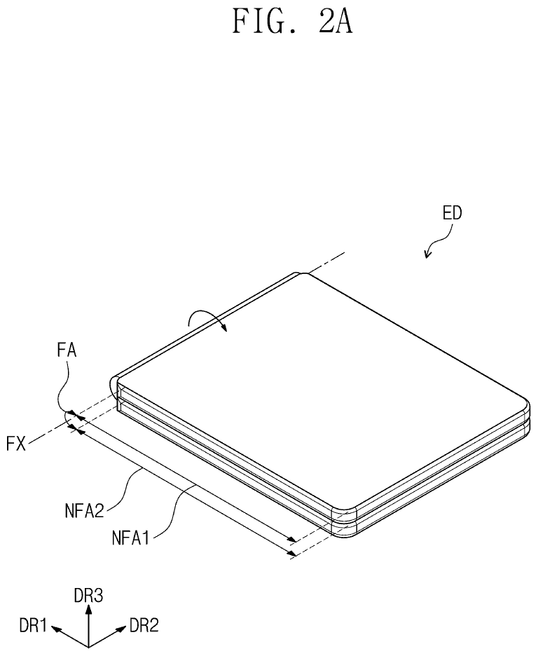

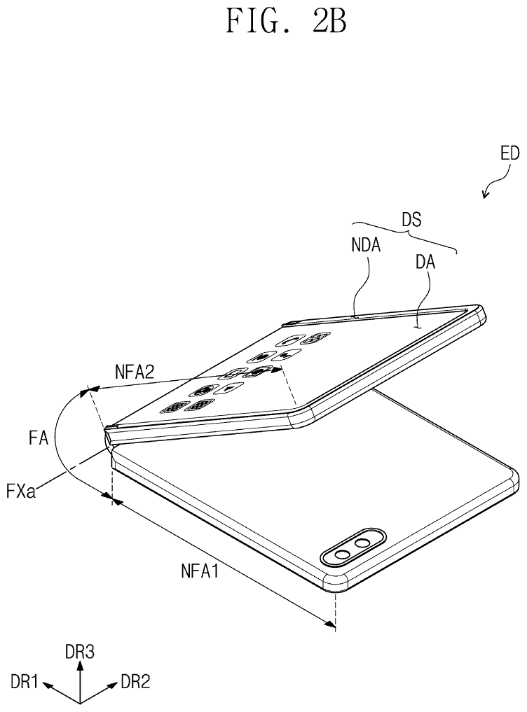

FIG. 1 is a perspective view of an electronic device ED according to an embodiment of the invention. FIGS. 2A and 2B are views illustrating a state in which the electronic device ED illustrated in FIG. 1 is folded.

Referring to FIG. 1, an electronic device ED according to an embodiment of the invention may have a rectangular shape which has long sides extending in a first direction DR1, and short sides extending in a second direction DR2 crossing the first direction DR1. However, an embodiment of the invention is not limited thereto, and the electronic device ED may have various planar shapes, such as a circular or polygonal shape. The electronic device ED may be a flexible electronic device.

Hereinafter, a direction, which is substantially perpendicular to a plane defined by the first direction DR1 and the second direction DR2 crossing each other, is defined as a third direction DR3. A thickness of the electronic device ED and various components or layers thereof may be defined along the third direction (DR3) as a thickness direction. Also, in this specification, the wording “when viewed on a plane” may be defined as a state when viewed in the third direction DR3. Additionally, in this specification, the wording “overlapping” may be referred to as a state in which components are disposed to overlap each other when viewed on a plane (e.g., along the thickness direction).

The electronic device ED may include a folding region FA and a non-folding region provided in plural including a plurality of non-folding regions NFA1 and NFA2. The non-folding regions NFA1 and NFA2 may include a first non-folding region NFA1 and a second non-folding region NFA2. The folding region FA may be disposed between the first non-folding region NFA1 and the second non-folding region NFA2. The first non-folding region NFA1, the folding region FA, and the second non-folding region NFA2 may be arranged in order along the first direction DR1.

For example, one folding region FA and two non-folding regions NFA1 and NFA2 are illustrated, but the number of the folding region FA and the number of the non-folding regions NFA1 and NFA2 are not limited thereto. For example, the electronic device ED may include more than two non-folding regions and a plurality of folding regions disposed with the non-folding regions therebetween.

An upper surface of the electronic device ED may be defined as a display surface DS and be a flat surface defined by the first direction DR1 and the second direction DR2 crossing each other. Images IM generated from the electronic device ED may be provided to outside the electronic device ED, such as to users thereof, through the display surface DS.

The display surface DS may include a display region DA and a non-display region NDA which is adjacent to the display region DA. The display region DA may display images IM, and the non-display region NDA may not display images IM. In the plan view, the non-display region NDA may surround the display region DA and define a border of the electronic device ED printed in a predetermined color.

Although not illustrated, the electronic device ED may include a plurality of sensors and a functional component such as at least one camera.

Referring to FIG. 2A, the electronic device ED may be a foldable electronic device ED which is folded or unfolded. For example, the electronic device ED may be foldable such that the folding region FA is bent with respect to a folding axis FX parallel to the second direction DR2. The electronic device ED may be folded to define a curvature radius (R). The folding axis FX may be defined as a short axis parallel to a cross-section of the electronic device ED.

When the electronic device ED is folded, the electronic device ED may be in-folded such that the first non-folding region NFA1 and the second non-folding region NFA2 may face each other and the display surface DS is not exposed to the outside. However, an embodiment of the invention is not limited thereto.

For example, as illustrated in FIG. 2B, the electronic device ED may be out-folded with respect to a folding axis FXa such that the first non-folding region NFA1 and the second non-folding region NFA2 face away from each other and the display surface DS is exposed to the outside. Alternatively, the electronic device ED may be in-folded and out-folded simultaneously, such as at different locations along the electronic device ED.

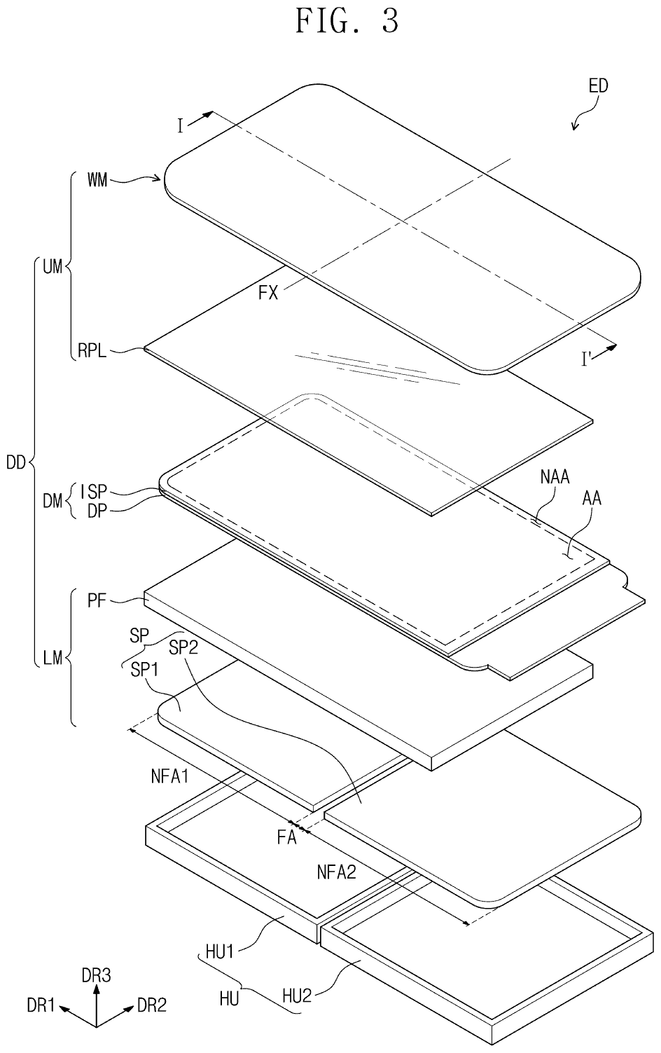

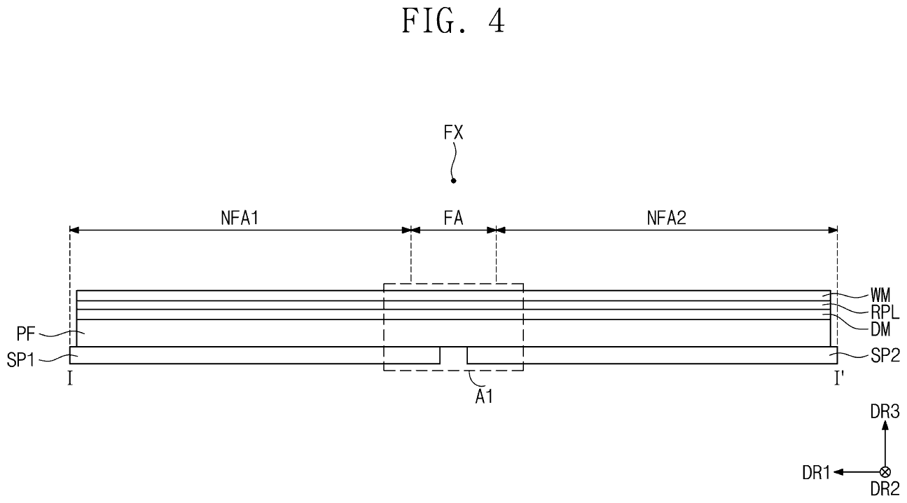

FIG. 3 is an exploded perspective view of an electronic device according to an embodiment of the invention. FIG. 4 is a cross-sectional view taken along line I-I′ illustrated in FIG. 3.

Referring to FIGS. 3 and 4, an electronic device ED may include a display device DD and a housing HU. Although not illustrated, the electronic device ED may further include a mechanical structure for controlling a folding operation of the display device DD.

The display device DD according to an embodiment of the invention may include a display module DM which displays images IM, an upper module UM disposed on the display module DM, and a lower module LM disposed below the display module DM. The display module DM may constitute a part of the display device DD, and particularly, images IM may be generated by the display module DM. The display module DM may display images IM in response to an electrical signal, and transmit/receive information about an external input. The display module DM may be defined as or divided into an active region AA and a peripheral region NAA. The active region AA may be defined as a region (or planar area) in which images IM provided from the display module DM are displayed.

The peripheral region NAA is adjacent to the active region AA. For example, the peripheral region NAA may surround the active region AA. However, this is illustrated as an example. The peripheral region NAA may be defined as having various shapes (e.g., planar shapes), and is not limited to any one embodiment. According to an embodiment, the active region AA of the display module DM may correspond to at least a portion of the display region DA of FIG. 1.

The display module DM may include a display panel DP and an input-sensing unit ISP. The display panel DP according to an embodiment of the invention may be a light-emitting display panel, and is not particularly limited. For example, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, etc. Hereinafter, the display panel DP is described as an organic light-emitting display panel.

The display panel DP may be a flexible display panel. Accordingly, the display panel DP may be entirely rolled, or folded or unfolded with respect to the folding axis FX. That is, the display panel DP (or the electronic device ED) may be rollable and/or foldable at a folding area including a respective folding axis FX.

The input-sensing unit ISP may be directly disposed on the display panel DP. According to an embodiment of the invention, the input-sensing unit ISP may be formed (or provided) on the display panel DP through a continuous process in a method of providing the display device DD. That is, when the input-sensing unit ISP is directly disposed on the display panel DP, an adhesive film is not disposed between the input-sensing unit ISP and the display panel DP. However, an embodiment of the invention is not limited thereto. An adhesive film may be disposed between the input-sensing unit ISP and the display panel DP. In this case, the input-sensing unit ISP and the display panel DP may not be manufactured (or provided) through a continuous process, but the input-sensing unit ISP may be manufactured through a separate process from the display panel DP and then fixed on an upper surface of the display panel DP by an intervening member such as an adhesive film.

The display panel DP generates images IM, and the input-sensing unit ISP acquires coordinate information about an external input to the display device DD such as a user's input (for example, touch event).

The upper module UM may include a window WM disposed on the display module DM. The window WM may include an optically transparent insulating material. Accordingly, images IM generated from the display module DM pass through the window WM, and may thus be easily recognized from outside the electronic device ED such as by a user. The detailed description of the window WM will be made with reference to FIG. 7A.

The upper module UM may further include one or more functional layers disposed between the display module DM and the window WM. As an example of the invention, the functional layer may be an anti-reflection layer RPL which blocks reflection of external light.

The anti-reflection layer RPL may prevent elements constituting the display module DM from being viewed from the outside (e.g., the outside of the electronic device ED) due to external light incident through a front surface like the display surface DS of the display device DD. The anti-reflection layer RPL may include a retarder and a polarizer. The retarder may be a film type or a liquid crystal coating type, and may include a λ/2 retarder and/or a λ/4 retarder. The polarizer may also be a film type or a liquid crystal coating type. The film type may include a stretched synthetic resin film, and the liquid crystal coating type may include liquid crystals arranged in a predetermined arrangement. The retarder and polarizer may form one polarizing film. The functional layer may further include a protective film disposed above or below the anti-reflection layer RPL.

The lower module LM may include a support plate SP disposed on a rear surface of the display module DM and supporting the display module DM, and a protective film PF disposed between the display module DM and the support plate SP. The support plate SP may include support plates the number of which corresponds to the number of the non-folding regions NFA1 and NFA2. As an example of the invention, the support plate SP may include a first support plate SP1 and a second support plate SP2 disposed to be spaced apart from the first support plate SP1. That is, the support plates of the support plate SP may be disconnected from each other at the folding region FA.

The first and second support plates SP1 and SP2 may be disposed to respectively correspond to the first and second non-folding regions NFA1 and NFA2. The first support plate SP1 is disposed to overlap the first non-folding region NFA1 of the display module DM, and the second support plate SP2 is disposed to overlap the second non-folding region NFA2 of the display module DM. The first and second support plates SP1 and SP2 may each include a metal material or a plastic material.

In a state in which the display module DM is unfolded as illustrated in FIG. 1, the first and second support plates SP1 and SP2 are disposed to be spaced apart from each other in (or along) the first direction DR1. In a state in which the display module DM is folded with respect to a folding axis FX as illustrated in FIG. 2A, the first and second support plates SP1 and SP2 may be disposed to be spaced apart from each other in (or along) the third direction DR3.

The first and second support plates SP1 and SP2 may be spaced apart from each other at the folding region FA. The first and second support plates SP1 and SP2 may extend from a non-folding region to partially overlap the folding region FA. That is, in the first direction DR1, a spacing distance between the first and second support plates SP1 and SP2 may be smaller than a total width of the folding region FA.

Although not illustrated, the support plate SP may further include a connection module for connecting the first and second support plates SP1 and SP2 to each other. The connection module may include a hinge module or an articulated module by which the support plates are hingedly or foldably connected to each other.

It is illustrated that the support plate SP includes two support plates SP1 and SP2, but an embodiment of the invention is not limited thereto. That is, when a plurality of folding axes FX are provided, the support plate SP may include a plurality of support plates separated with respect to the plurality of folding axes FX. Alternatively, the support plate SP may not be separated into the first and second support plates SP1 and SP2, but may be provided as an integrated shape, that is, connected to each other. In this case, a bending portion may be provided in the support plate SP to correspond to the folding region FA. The bending portion may be a solid or material portion of the support plate SP in which an opening is provided such as by penetrating a thickness portion of the support plate SP. Penetration of a partial thickness may provide a groove recessed from one surface of the support plate SP while penetration of a complete thickness may provide a through-hole.

The protective film PF may be disposed between the display module DM and the support plate SP. The protective film PF may be disposed below the display module DM, and may protect a rear surface of the display module DM. The protective film PF may include a synthetic resin film, for example, a polyimide film or a polyethyleneterephthalate film. However, this is presented as an example, and the protective film PF is not limited thereto.

The housing HU may be coupled to the display device DD, specifically, at window WM, and accommodate the display module DM and the lower module LM. It is illustrated that the housing HU includes first and second housings HU1 and HU2 separated from each other, but an embodiment of the invention is not limited thereto. Although not illustrated, the electronic device ED may further include a hinge structure for connecting the first and second housings HU1 and HU2.

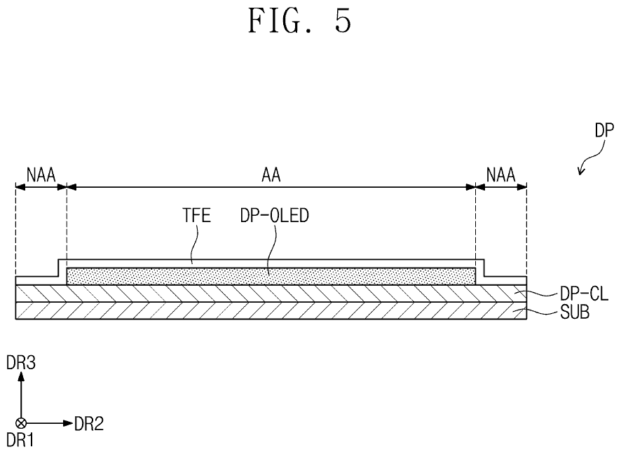

FIG. 5 exemplarily illustrates a cross-sectional view of a display panel DP illustrated in FIG. 3.

For example, FIG. 5 illustrates a cross section of a display panel DP when viewed in the first direction DR1.

Referring to FIG. 5, the display panel DP may include a substrate SUB, a circuit element layer DP-CL disposed on the substrate SUB, a display element layer DP-OLED disposed on the circuit element layer DP-CL, and a thin-film encapsulation layer TFE as an encapsulation layer covering the display element layer DP-OLED.

The substrate SUB may include an active region AA and a peripheral region NAA which is adjacent to, such as being around the active region AA. The substrate SUB may include a flexible plastic material such as polyimide (PI). The display element layer DP-OLED may be disposed on the active region AA.

A plurality of pixels PX may be disposed in the active region AA. The pixels PX may each be connected to a transistor disposed in the circuit element layer DP-CL, and include a light-emitting element disposed in the display element layer DP-OLED.

The thin-film encapsulation layer TFE may be disposed on the circuit element layer DP-CL so as to cover the display element layer DP-OLED. The thin-film encapsulation layer TFE may include inorganic layers and an organic layer which is between the inorganic layers. The inorganic layers may protect the pixels PX against moisture/oxygen. The organic layer may protect the pixels PX against foreign substances such as dust particles.

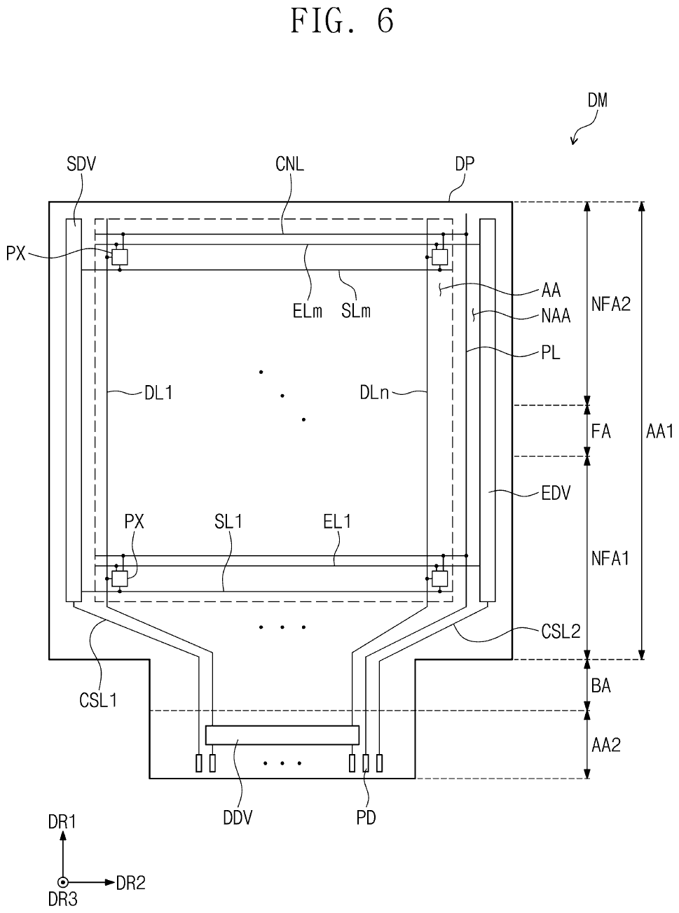

FIG. 6 is a plan view of the display panel DP illustrated in FIG. 5.

Referring to FIG. 6, a display module DM may include a display panel DP, a scan driver SDV, a data driver DDV, and an emission driver EDV.

The display panel DP may include a first region AA1, a second region AA2, and a bending region BA between the first region AA1 and the second region AA2. The bending region BA may extend in the second direction DR2, and the first region AA1, the bending region BA and the second region AA2 may be arranged in order in the first direction DR1.

The first region AA1 may include an active region AA and a peripheral region NAA which is adjacent to the active region AA. The peripheral region NAA may surround the active region AA. The active region AA may display images IM (e.g., a display area), and the peripheral region NAA may not display images IM. The second region AA2 and the bending region BA may not display images IM (e.g., a non-display area). While the first region AA1 may include a portion of the peripheral region NAA which is adjacent to the active region AA, the second region AA2 and the bending region BA may constitute a remaining portion of the peripheral region NAA, without being limited thereto.

When viewed in the second direction DR2, the first region AA1 may include a first non-folding region NFA1, a second non-folding region NFA2, and a folding region FA between the first non-folding region NFA1 and the second non-folding region NFA2.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power supply line PL, a plurality of connection lines CNL, and a plurality of pads PD. Here, ‘m’ and ‘n’ are natural numbers. The pixels PX may be disposed in the active region AA and be variously connected to the scan lines SL1 to SLm, the data lines DL1 to DLn, and the emission lines EL1 to ELm.

The scan driver SDV and the emission driver EDV may be disposed in the peripheral region NAA. The scan driver SDV and the emission driver EDV may be disposed in the peripheral region NAA adjacent to each of both sides, of the first region AA1, which are opposed to each other in the second direction DR2 (e.g., opposing sides). The data driver DDV may be disposed in the second region AA2. The data driver DDV may be manufactured in a form of an integrated circuit chip and be mounted on the second region AA2.

The scan lines SL1 to SLm may extend in the second direction DR2 to be connected to the scan driver SDV. The data lines DL1 to DLn may extend in the first direction DR1 to be connected to the data driver DDV via the bending region BA. The emission lines EL1 to ELm may extend in the second direction DR2 to be connected to the emission driver EDV.

The power supply line PL may extend in the first direction DR1 and be disposed in the peripheral region NAA. The power supply line PL may be disposed between the active region AA and the emission driver EDV, but is not limited thereto. The power supply line PL may be disposed between the active region AA and the scan driver SDV.

The power supply line PL may extend to the second region AA2 via the bending region BA. When viewed on a plane, the power supply line PL may extend toward a lower end of the second region AA2. The power supply line PL may receive a driving voltage.

The connection lines CNL may extend in the second direction DR2 and be arranged in the first direction DR1. The connection lines CNL may be connected to the power supply line PL and the pixels PX. The driving voltage may be applied to the pixels PX via the power supply line PL and the connection lines CNL which are connected to each other.

The first control line CSL1 may be connected to the scan driver SDV and extend toward a lower end of the second region AA2 via the bending region BA. The second control line CSL2 may be connected to the emission driver EDV and extend toward the lower end of the second region AA2 via the bending region BA. The data driver DDV may be disposed between the first control line CSL1 and the second control line CSL2.

When viewed on a plane, the pads PD may be disposed adjacent to the lower end of the second region AA2. The data driver DDV, the power supply line PL, the first control line CSL1, and the second control line CSL2 may be connected to the pads PD.

The data lines DL1 to DLn may be connected to the corresponding pads PD via the data driver DDV. For example, the data lines DL1 to DLn may be connected to the data driver DDV, and the data driver DDV may be connected to the pads PD respectively corresponding to the data lines DL1 to DLn.

Although not illustrated, an external component like a printed circuit board may be connected to the display panel DP at a pad area thereof (e.g., where the pads PD are arranged), and a timing controller and a voltage generator may be disposed on the printed circuit board. The timing controller may be manufactured (or provided) as an integrated circuit chip and be mounted on the printed circuit board. The timing controller and the voltage generator may be connected to the display panel DP at the pads PD, via the printed circuit board.

The timing controller may control operations of the scan driver SDV, the data driver DDV, and the emission driver EDV. The timing controller may generate a scan control signal, a data control signal, and an emission control signal in response to control signals received from the outside. The voltage generator may generate a driving voltage.

The scan control signal may be provided to the scan driver SDV via the first control line CSL1. The emission control signal may be provided to the emission driver EDV via the second control line CSL2. The data control signal may be provided to the data driver DDV. The timing controller may receive image signals from the outside, convert data formats of the image signals so as to meet interface specifications of the data driver DDV, and provide the converted signals to the data driver DDV.

The scan driver SDV may generate a plurality of scan signals in response to a scan control signal. The scan signals may be applied to the pixels PX via the scan lines SL1 to SLm. The scan signals may be sequentially applied to the pixels PX.

The data driver DDV may generate a plurality of data voltages corresponding to image signals in response to a data control signal. The data voltages may be applied to the pixels PX via the data lines DL1 to DLn. The emission driver EDV may generate a plurality of emission signals in response to an emission control signal. The emission signals may be applied to the pixels PX via the emission lines EL1 to ELm.

The pixels PX may receive data voltages in response to the scan signals. The pixels PX may display images IM by emitting light having a luminance corresponding to the data voltages in response to the emission signals. The emission time of the pixels PX may be controlled by the emission signals.

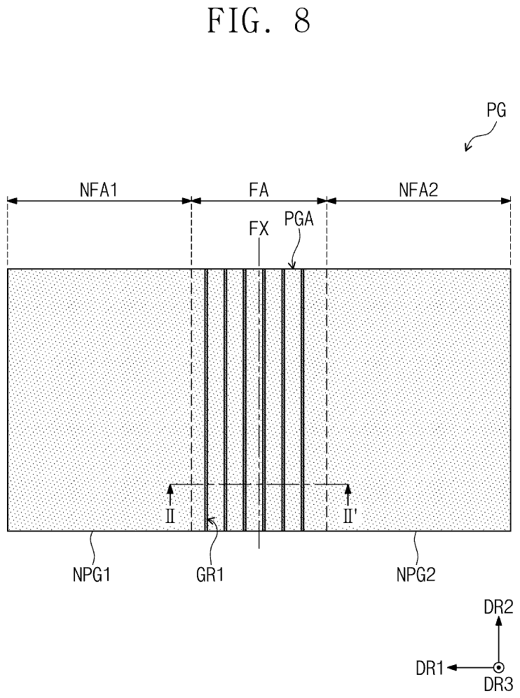

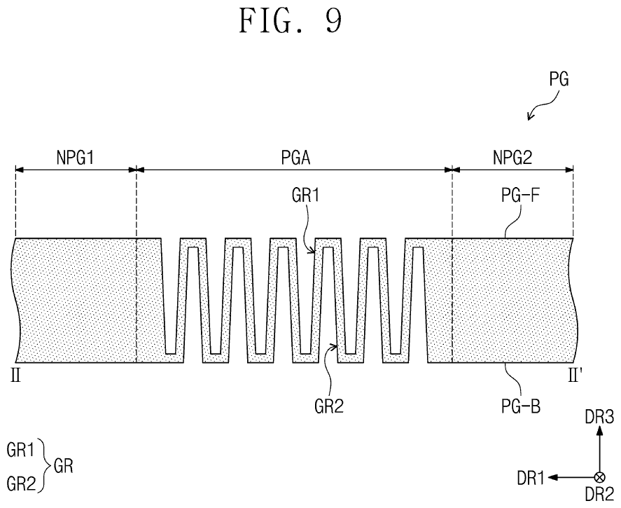

FIG. 7A is an enlarged cross-sectional view corresponding to the first region A1 illustrated in FIG. 4. FIGS. 7B to 7D are enlarged cross-sectional views of a display device DD according to an embodiment of the invention. FIG. 8 is a plan view of a pattern glass PG illustrated in FIG. 7A. FIG. 9 is a cross-sectional view taken along line II-II′ illustrated in FIG. 8.

For example, FIGS. 7B to 7D are enlarged cross-sectional views of a part corresponding to the first region A1 illustrated in FIG. 4.

Referring to FIGS. 7A and 9, a window WM may include a pattern glass PG, a lower adhesive layer W_AL1, an upper adhesive layer W_AL2, a protective layer PLL, and a filling member or filling pattern such as filling resins PT1 and PT2.

The pattern glass PG may include a glass material. The pattern glass PG as a patterned glass may include a patterned portion PGA, and a non-patterned portion provided in plural including first and second non-patterned portions NPG1 and NPG2. The first non-patterned portion NPG1, the patterned portion PGA and the second patterned portion NPG2 may be arranged in order in the first direction DR1. The patterned portion PGA may be disposed between the first and second non-patterned portions NPG1 and NPG2. Substantially, the first non-patterned portion NPG1, the patterned portion PGA and the second non-patterned portion NPG2 may be integrally formed. Here, the patterned portion PGA and the non-patterned portion may be a single, unitary body.

The patterned portion PGA may overlap a folding region FA. The first non-patterned portion NPG1 may overlap a first non-folding region NFA1. The second non-patterned portion NPG2 may overlap a second non-folding region NFA2.

The pattern glass PG may include an upper surface PG-F and a lower surface PG-B. The upper surface PG-F and the lower surface PG-B of the pattern glass PG may be referred to as two surfaces opposed to each other in the third direction DR3. The lower surface PG-B may be defined as a surface facing an anti-reflection layer RPL. The upper surface PG-F may be furthest from the display module DM while the lower surface PG-B is closest to the display module DM, along the thickness direction.

A groove provided in plural including a plurality of grooves GR are defined in the patterned portion PGA. The grooves GR may include first grooves GR1 and second grooves GR2. The first grooves GR1 may be defined recessed from the upper surface PG-F and open at the upper surface PG-F of the pattern glass PG. When viewed on a plane, the first grooves GR1 may extend (lengthwise) in the second direction DR2, and be arranged to be spaced apart from each other in the first direction DR1. The first grooves GRI may extend in a direction from the upper surface PG-F toward the lower surface PG-B of the pattern glass PG, in the third direction DR3. The first grooves GR1 may extend more than half the thickness of the pattern glass PG. The first grooves GR1 may have total depths greater than half the total thickness of the pattern glass PG.

The second grooves GR2 may be defined recessed from the lower surface PG-B and open at the lower surface PG-B of the pattern glass PG. When viewed on a plane, the second grooves GR2 may be arranged to be spaced apart from each other in the first direction DR1. Although not illustrated, when viewed on a plane, the second grooves GR2 may each extend (lengthwise) in the second direction DR2. The second grooves GR2 may extend in a direction from the lower surface PG-B toward the upper surface PG-F of the pattern glass PG, in the third direction DR3. The second grooves GR2 may have total depths greater than half the total thickness of the pattern glass PG.

For example, the first grooves GR1 and the second grooves GR2 may have identical or similar shapes in cross-section, and be symmetrical to each other with respect to the third direction DR3. The first grooves GRI and the second grooves GR2 may be alternately arranged in the first direction DR1.

Referring to FIGS. 7A and 7B, the filling resins PT1 and PT2 may include first filling resins PT1 as an upper filling resin and second filling resins PT2 as a lower filling resin. The first filling resins PT1 may be disposed in the first grooves GR1. The first filling resins PT1 may have a shape (or volume) corresponding to that of the first grooves GR1. The first filling resins PT1 may each be a discrete pattern corresponding to a respective shape (or volume) of a first groove GR1. Upper surfaces of the first filling resins PT1 may be coplanar with the upper surface PG-F of the patterned glass. The second filling resins PT2 may be disposed in the second grooves GR2.

At least one among the first filling resins PT1 and the second filling resins PT2 may protrude beyond the upper surface or the lower surface of the pattern glass PG. Here, a portion of a respective filling member may extend from a groove to outside of the pattern glass PG, at a major surface thereof. For example, as illustrated in FIG. 7A, the second filling resins PT2 may protrude beyond the lower surface of the pattern glass PG. The second filling resins PT2 may be more adjacent to the display module DM than the lower surface PG-B of the pattern glass PG.

The second filling resins PT2 may include (2-1)-th filling resins PT2-1 and (2-2)-th filling resins PT2-2. The (2-1)-th filling resins PT2-1 may be portions of the second filling resins PT2 which fill the second grooves GR2. The (2-2)-th filling resins PT2-2 may be a portion of the second filling resins PT2 which is disposed outside the second grooves GR2. The (2-2)-th filling resins PT2-2 may be disposed along the lower surface PG-B of the pattern glass PG. The (2-2)-th filling resins PT2-2 may be more adjacent to the display module DM (e.g., closer to) than the pattern glass PG.

A lower surface FB of the (2-2)-th filling resins PT2-2 may include a first flat portion PLA1 and a plurality of first inclined surfaces SLA1 which respectively extend from opposing ends of the first flat portion PLA1 in the first direction DR1. The first flat portion PLA1 may be parallel to a plane defined by the first direction DR1 and the second direction DR2. The first inclined surfaces SLA1 may be adjacent to outermost portions of the (2-2)-th filling resins PT2-2 which are opposed to each other in the first direction DR1. The lower surface FB of the (2-2)-th filling resins PT2-2 may be defined as a surface facing the anti-reflection layer RPL.

Heights of the first inclined surfaces SLA1 from the lower surface FB at the first flat portion PLA1 may increase as a distance from the lower surface FB at the first flat portion PLA1 increases. Thicknesses of the (2-2)-th filling resins PT2-2 relative to the lower surface PG-B of the pattern glass PG may decrease as a distance from the lower surface FB at the first flat portion PLA1 increases.

The total width of the (2-2)-th filling resins PT2-2 in the first direction DR1 may be smaller than the total width of the patterned portion PGA in the first direction DR1. However, this is illustrated as an example, and as illustrated in FIG. 7B, the total width of the (2-2)-th filling resins PT2-2 in the first direction DR1 may be the same as the total width of the patterned portion PGA in the first direction DR1. The (2-1)-th filling resins PT2-1 and (2-2)-th filling resins PT2-2 may together provide a single, unitary body of the second filling resins PT2.

Substantially, the first and second filling resins PT1 and PT2 may include the same material as each other. For example, the first and second filling resins PT1 and PT2 may each include a synthetic resin material. The first and second filling resins PT1 and PT2 may each include a material having the same refractive index as that of the pattern glass PG. Accordingly, light propagating toward the first and second filling resins PT1 and PT2, and the pattern glass PG may not be refracted at boundaries between the first and second filling resins PT1 and PT2 and the pattern glass PG. Therefore, the boundaries between the first and second filling resins PT1 and PT2 and the pattern glass PG may be invisible to a user.

For example, the first and second filling resins PT1 and PT2 may each include at least one selected from a urethane-based resin, an epoxy-based resin, a polyester-based resin, a polyether-based resin, an acrylate-based resin, an acrylonitrile-butadiene-styrene resin (ABS resin), and rubber. Specifically, the first and second filling resins PT1 and PT2 may each include at least one among phenylene, polyethyleneterephthalate (PET), polyimide (PI), polyamide (PAI), polyethylene naphthalate (PEN), and polycarbonate (PC).

Referring again to FIG. 7A, the protective layer PLL may include a first protective layer PLL1 (e.g., a first sub-layer) and a second protective layer PLL2 (e.g., a second sub-layer). The first protective layer PLL1 may be disposed below the pattern glass PG. The second protective layer PLL2 may be disposed above the pattern glass PG.

The protective layer PLL may perform a function of protecting the pattern glass PG against an external impact. The protective layer PLL may include a synthetic resin material. As an example of the invention, the protective layer PLL may include at least one selected from a urethane-based resin, an epoxy-based resin, a polyester-based resin, a polyether-based resin, an acrylate-based resin, an acrylonitrile-butadiene-styrene resin (ABS resin), and rubber. Specifically, the protective layer PLL may include at least one among phenylene, polyethyleneterephthalate (PET), polyimide (PI), polyamide (PAI), polyethylene naphthalate (PEN), and polycarbonate (PC).

The lower adhesive layer W_AL1 may be disposed on the lower surface PG-B of the pattern glass PG. The lower adhesive layer W_AL1 may be disposed between the pattern glass PG and the first protective layer PLL1. The lower adhesive layer W_AL1 may be disposed between the pattern glass PG and the first protective layer PLL1, and thus attach the first protective layer PLL1 to the lower surface PG-B of the pattern glass PG. The lower adhesive layer W_AL1 may cover the (2-2)-th filling resin PT2-2.

The upper adhesive layer W_AL2 may be disposed on the upper surface PG-F of the pattern glass PG. The first filling resins PT1 and the patterned glass may each contact the upper adhesive layer W_AL2. Elements which are in contact may form an interface therebetween, without being limited thereto. The upper adhesive layer W_AL2 may be disposed between the pattern glass PG and the second protective layer PLL2. The upper adhesive layer W_AL2 may be disposed between the pattern glass PG and the second protective layer PLL2, and thus attach the second protective layer PLL2 to the upper surface PG-F of the pattern glass PG. The upper adhesive layer W_AL2 may cover the first filling resins PT1.

The lower adhesive layer W_AL1 and the upper adhesive layer W_AL2 may each include an optically transparent adhesive material. The lower adhesive layer W_AL1 and the upper adhesive layer W_AL2 may include a pressure sensitive adhesive (PSA), an optical clear adhesive (OCA), or an optical clear resin (OCR).

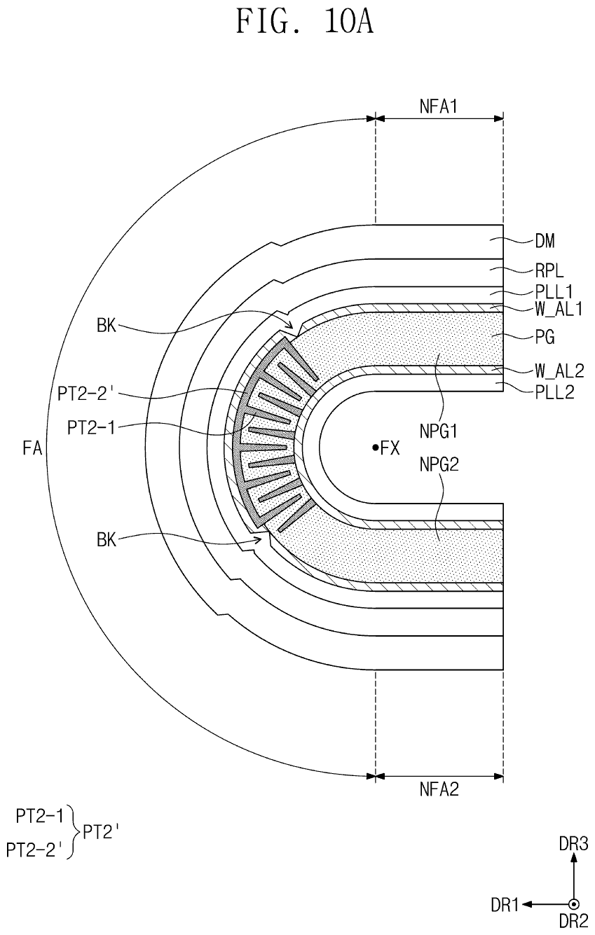

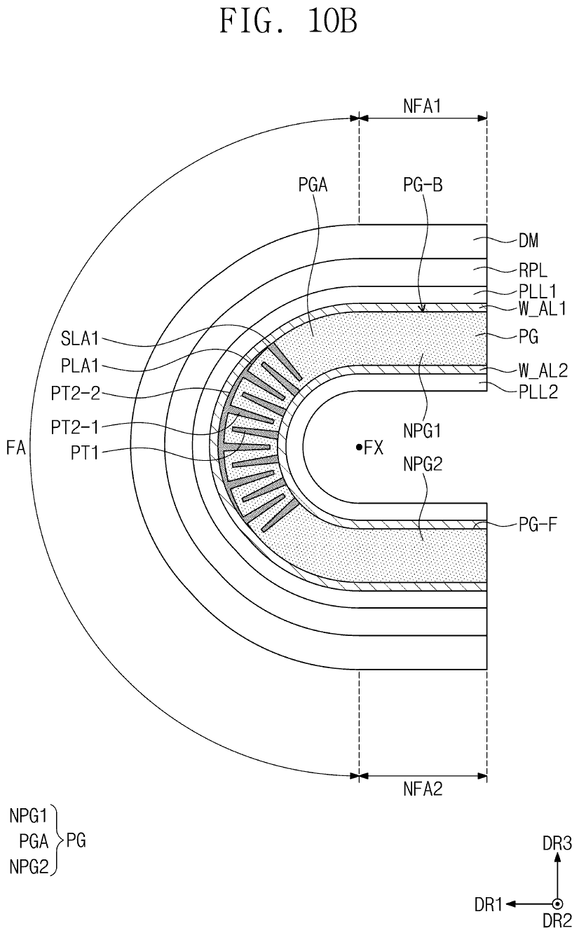

FIG. 10A is a cross-sectional view illustrating a state in which a comparative display device according to Comparative Example is folded. FIG. 10B is a cross-sectional view illustrating a state in which the display device DD illustrated in FIG. 7A is folded.

For example, in FIGS. 10A and 10B, the lower module LM, and the first adhesive layer AF1 illustrated in FIG. 7A are omitted for convenience of illustration.

Among components illustrated in FIGS. 10A and 10B, the description of components which are described with reference to the above-described drawings and are identical or similar to the described components will be omitted or abbreviated.

Referring to FIG. 10A, a lower surface of a (2-2)-th filling resin PT2-2′ may not include an inclined surface SLA1. The lower surface of the (2-2)-th filling resin PT2-2′ may be disposed to form a stepped portion with respect to a lower surface PG-B of a pattern glass PG.

A folding region FA may be in-folded with respect to the folding axis FX. The folding region FA may be bent into a curved shape. When the folding region FA is folded, a patterned portion PGA of the pattern glass PG overlapping the folding region FA, a portion of an anti-reflection layer RPL, and a portion of a display module DM may be bent together with each other.

When the pattern glass PG is bent, a lower adhesive layer W_AL1 disposed on the lower surface PG-B of the pattern glass PG may receive a tensile stress. In this case, the lower surface of the (2-2)-th filling resin PT2-2′ and the lower surface PG-B of the pattern glass PG may be disposed to form a stepped portion therebetween. Accordingly, a buckling BK may occur in a portion of the lower adhesive layer W_AL1 which is adjacent to a boundary between the lower surface of the (2-2)-th filling resin PT2-2′ and the lower surface PG-B of the pattern glass PG (e.g., at the stepped portion).

When the buckling BK occurs in the lower adhesive layer W_AL1, a first protective layer PLL1 bonded to the lower surface PG-B of the pattern glass PG via the lower adhesive layer W_AL1, an anti-reflection layer RPL bonded to the first protective layer PLL1, and a display module DM bonded to the anti-reflection layer RPL may be peeled off from the pattern glass PG. Accordingly, a portion, of the lower adhesive layer W_AL1, in which the buckling BK occurs, and the first protective layer PLL1 the anti-reflection layer RPL, and the display module DM which are separated from the lower adhesive layer W_AL1, are viewed from the outside, and thus the surface quality of the display device DD may be deteriorated.

Referring to FIG. 10B, the lower surface FB of a (2-2)-th filling resin PT2-2 according to an embodiment of the invention may include first inclined surfaces SLA1 along which a thickness of the (2-2)-th filling resin PT2-2 increases in a direction from a location where the lower surface PG-B of the pattern glass PG meets an end of the second filling resin PT2 (e.g., a boundary) toward the folding region FA. When the display device DD is folded at the folding region FA, at a boundary between the lower surface FB of the (2-2)-th filling resin PT2-2 and the lower surface PG-B of the pattern glass PG, the curvature of the lower surface FB of the (2-2)-th filling resin PT2-2 may be substantially the same as the curvature of the lower surface PG-B of the pattern glass PG. Accordingly, a lower surface of the lower adhesive layer W_AL1 may be bent, without having a stepped portion, into a shape corresponding to a continuous profile (e.g., no stepped portion) formed by the lower surface PG-B of the pattern glass PG together with the lower surface FB of the (2-2)-th filling resin PT2-2.

Therefore, it is possible to prevent the buckling BK (see FIG. 10A) from occurring in the lower adhesive layer W_AL1 which covers the (2-2)-th filling resin PT2-2. The first protective layer PLL1 bonded to the lower surface PG-B of the pattern glass PG via the lower adhesive layer W_AL1, the anti-reflection layer RPL bonded to the first protective layer PLL1, the display module DM bonded to the anti-reflection layer RPL may not be peeled off from the pattern glass PG. Therefore, the surface quality of the display device DD may be improved.

Referring to FIG. 7A, the display device DD (see FIG. 3) may further include first to third adhesive layers AF1 to AF3. The first adhesive layer AF1 may be disposed between the anti-reflection layer RPL and the display module DM. The anti-reflection layer RPL and the display module DM may be bonded to each other via the first adhesive layer AF1.

The second adhesive layer AF2 may be disposed between the display module DM and the protective film PF. The display module DM and the protective film PF may be bonded to each other via the second adhesive layer AF2.

The third adhesive layer AF3 may be disposed between the protective film PF and support plates SP1 and SP2. The third adhesive layer AF3 may include a (3_1)-th adhesive layer AF3_1 and a (3_2)-th adhesive layer AF3_2. The (3_1)-th adhesive layer AF3_1 and the (3_2)-th adhesive layer AF3_2 may be disposed to be spaced apart from each or disconnected from each other in the first direction DR1. The (3_1)-th adhesive layer AF3_1 and the (3_2)-th adhesive layer AF3_2 may be disposed to respectively correspond to first and second non-folding regions NFA1 and NFA2. The (3_1)-th adhesive layer AF3_1 may be disposed to overlap the first non-folding region NFA1, and the (3_2)-th adhesive layer AF3_2 may be disposed to overlap the second non-folding region NFA2.

Referring to FIG. 7C, a display device DDa according to an embodiment of the invention may be in-folded or out-folded with respect to the folding axes FX and FXa, respectively. In this case, the first filling resin PT1a and the second filling resin PT2 may respectively protrude beyond the upper surface PG-F and the lower surface PG-B of the pattern glass PG. The second filling resin PT2 has been described in FIG. 7A, and will be omitted. That is, the protruded portion of a respective filling resin may be disposed on a side of the pattern glass PG which receives a tensile stress in bending of the display panel DP at the folding regions FA.

A portion of the first filling resin PT1a may extend out of the first grooves GR1 to be disposed on the upper surface PG-F of the pattern glass PG. The height of the upper surface of the first filling resin PT1a may be greater than the height of the upper surface of the pattern glass PG. That is, the first filling resin PT1a may protrude further than the upper surface PG-F. The upper adhesive layer W_AL2 may cover a (1-2)-th filling resin PT1-2.

The first filling resin PT1a may include a (1-1)-th filling resin PT1-1 and the (1-2)-th filling resin PT1-2. The (1-1)-th filling resin PT1-1 may fill first grooves GR1. The (1-2)-th filling resin PT1-2 may be disposed on the upper surface of the patterned portion PGA.

An upper surface UB of the (1-2)-th filling resin PT1-2 may include a second flat portion PLA2 and second inclined surfaces SLA2 which respectively extend from opposing sides of the second flat portion PLA2 in the first direction DR1. Heights of the second inclined surfaces SLA2 relative to the upper surface UB may become lower as a distance from the second flat portion PLA2 increases. Thicknesses of the (1-2)-th filling resins PT1-2 relative to the upper surface UB may become smaller as a distance from the second flat portion PLA2 increases. The upper surface UB of the (1-2)-th filling resins PT1-2 may be defined as a surface facing a second protective layer PLL2.

For example, the total width of the (1-2)-th filling resin PT1-2 in the first direction DR1 may be smaller than the total width of the patterned portion PGA in the first direction DR1. However, the width of the (1-2)-th filling resin PT1-2 in the first direction DR1 is not limited thereto.

When the display device DDa is out-folded, the (1-2)-th filling resin PT1-2 may prevent the buckling BK (see FIG. 10B) from occurring in the upper adhesive layer W_AL2. The principle that the occurrence of the buckling BK (FIG. 10B) is prevented has been described above, and thus will be omitted.

Referring to FIG. 7D, a display device DDb according to an embodiment of the invention may be out-folded as illustrated in FIG. 2B. In this case, a first filling resin PT1a may protrude beyond the upper surface PG-F of the pattern glass PG. The first filling resin PT1a has been described in detail in FIG. 7C, and thus the description of the first filling resin PT1a will be omitted.

A second filling resin PT2a may not protrude beyond the lower surface PG-B of the pattern glass PG. The second filling resin PT2a may be substantially the same as the (2-1)-th filling resin PT2-1 illustrated in FIG. 7A. Here, the second filling resin PT2a may be a discrete pattern corresponding to the shape (or volume) of a second groove GR2.

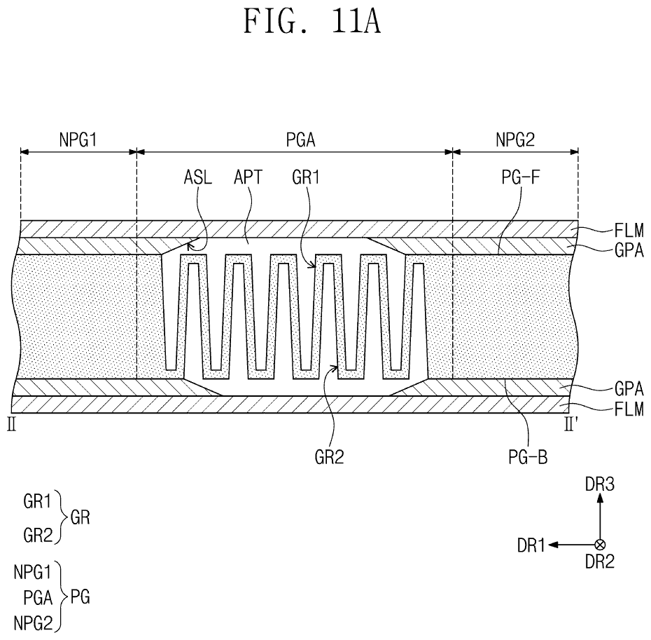

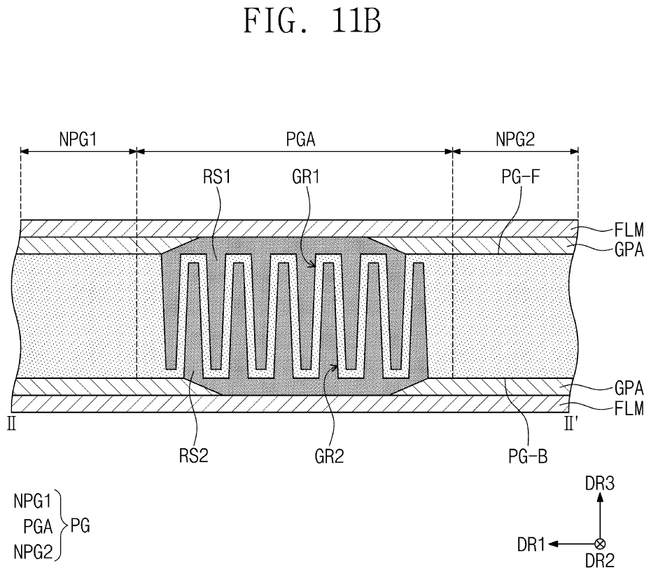

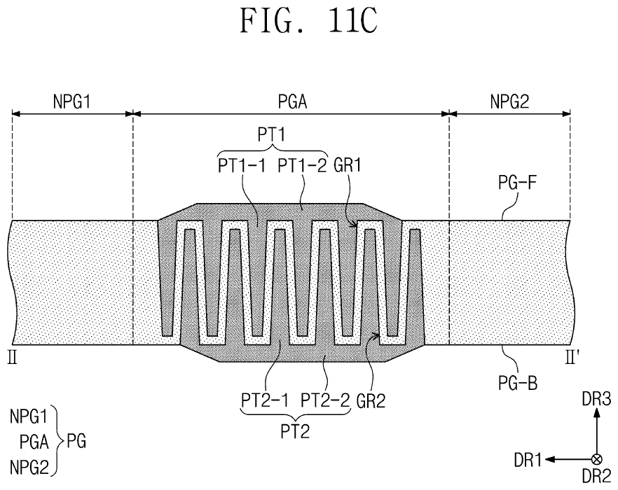

FIGS. 11A to 11C are views for describing a method for manufacturing (or providing) the first filling resin PT1 and the second filling resin PT2 illustrated in FIG. 7C.

For example, FIGS. 11A to 11C are cross-sectional views.

Among components illustrated in FIGS. 11A to 11C, the description of components which are described with reference to the above-described drawings and are identical or similar to the described components will be omitted or abbreviated.

Referring to FIG. 11A, a method for manufacturing (or providing) the window WM (see FIG. 7C) may include providing guide adhesive layers GPA on an upper surface PG-F and a lower surface PG-B of a pattern glass PG, respectively. The guide adhesive layers GPA may be disposed on an upper surface portion at a first non-patterned portion NPG1 and an upper surface portion at a second non-patterned portion NPG2. The guide adhesive layers GPA may be separated from (e.g., disconnected from) each other on a patterned portion PGA and be spaced apart in the first direction DR1.

Inner side surfaces ASL of the guide adhesive layers GPA facing each other in the first direction DR1 may include inclined side surfaces. Inner side surfaces ASL may be inclined toward the upper surface PG-F and the lower surface PG-B of the pattern glass PG, respectively, in a direction from the patterned portion PGA toward a non-patterned portion among the first and second non-patterned portions NPG1 and NGP2. Thicknesses of the guide adhesive layers GPA at a folding area of the pattern glass PG may increase as a distance to the first and second non-patterned portions NPG1 and NPG2 decreases. The pattern glass PG having the guide adhesive layers GPA thereon may provide a preliminary window structure.

Release films FLM may be disposed on an upper part and a lower part of the pattern glass PG within the preliminary window structure. The release films FLM may be bonded to the pattern glass PG via the guide adhesive layers GPA.

Filling spaces APT may be defined by the inner side surfaces ASL of the guide adhesive layers GPA and upper surfaces and lower surfaces of the release films FLM. The filling spaces APT may be sealed by the inner side surfaces ASL of the guide adhesive layers GPA and the upper surface and the lower surface of the release films FLM.

The filling spaces APT may be respectively in communication with corresponding grooves GR among the grooves GR to define an empty space or volume in which a folding area filling member may be provided. The filling space APT defined in the upper part of the patterned portion PGA among the filling spaces APT may be defined to be continuous with first grooves GR1. The filling space APT defined in the lower part of the patterned portion PGA among the filling spaces APT may be defined to be continuous with second grooves GR2.

Referring to FIG. 11B, after sealing the patterned portion PGA, filling the filling spaces APT with a resin material may be performed. For example, the resin material may fill the filling spaces APT through a capillary phenomenon. In an embodiment, one or more groove among the corresponding grooves and a corresponding filling space may be open along the second direction DR2, without being limited thereto. However, an embodiment of the invention is not limited thereto, and filling with the resin material may be performed through various methods.

The resin material which has filled the volume of the filling spaces APT, may have a shape corresponding to the inner side surfaces ASL of the guide adhesive layers GPA, together with shapes of the upper surfaces and the lower surfaces of the release films FLM which face a respective guide adhesive layer GPA. The resin material which has filled the volume of the filling spaces, may have a shape corresponding to the first grooves GR1 and the second grooves GR2 which are open to the respective filling space APT.

A first resin material RS1 may be provided to form a pattern of the first filling resin PT1. A second resin material RS2 may be provided to form a pattern of the second filling resin PT2. The first and second resin materials RS1 and RS2 may be the same material, without being limited thereto. The first and second resin materials RS1 and RS2 may be uncured resin material.

Although not illustrated, after the respective resin material is cured, the first filling resin PT1 and the second filling resin PT2 illustrated in FIG. 7C may be formed.

Referring to FIGS. 7C and 11C, after the first filling resin PT1 and the second filling resin PT2 are formed, the guide adhesive layers GPA (see FIG. 11B) and the release films FLM may be removed from the pattern glass PG to provide a window WM including the pattern glass PG having filling patterns which are at opposite surfaces of the pattern glass PG and fill respective grooves at the surfaces.

Although not illustrated, after the guide adhesive layers GPA (see FIG. 11B) and the release films FLM are removed, the pattern glass PG having the filling patterns is disposed on the display module DM as illustrated in FIG. 7C, and then the display device DDa may be manufactured.

Since the upper surface of the first filling resin PT1a and the lower surface of the second filling resin PT2 have the inclined surfaces SLA1 and SLA2, it is possible to prevent buckling from occurring in the lower adhesive layer W_AL1 or the upper adhesive layer W_AL2 when the display device DDa (see FIG. 7C) is folded. Therefore, the surface quality of the display device DDa (see FIG. 7C) may be improved.

While FIGS. 11A-11C illustrate forming the structure in FIG. 7C, it will be understood that similar processes may be used to form the structure in FIG. 7A, 7B or 7D. In an embodiment, for example, the method may include providing a patterned glass which is foldable together with a display panel DP, the patterned glass including a patterned portion PGA corresponding to a folding region FA of the display panel DP and a non-patterned portion which is adjacent to the patterned portion PGA in a first direction DR1, and each of the patterned portion PGA and the non-patterned portion including an upper surface and a lower surface which is opposite to the upper surface and closer to the display surface DS of the display panel DP than the upper surface, providing guide adhesive layers on each of the upper surface and the lower surface of the non-patterned portion, the guide adhesive layers on a respective surface among the upper and lower surfaces including inclined side surfaces facing each other across the patterned portion and defining a filling space with the patterned portion PGA, filling the filling space with a resin material, and providing the patterned glass having the filling space which is filled with the resin material, on the display panel DP. Here, the filling space may be an upper filling space between inclined side surfaces of upper guide adhesive layers and the patterned glass or a lower filling space between inclined side surfaces of lower guide adhesive layers.

In an embodiment, to provide a filling resin without a protruded portion, a release film (or guide adhesive layer) may be provided directly on the patterned portion to extend across respective grooves. Here, the resin may extend up to the release film and have ends which are coplanar with a major surface of the patterned glass.

To form the structure in FIG. 7C, for example, the method may further include the guide adhesive layers including upper guide adhesive layers on the upper surface of the non-patterned portion and defining an upper filling space with the first groove, and lower guide adhesive layers on the lower surface of the non-patterned portion and defining a lower filling space with the second groove. Here, providing the resin material may include filling the resin material in the upper filling space to define a first filling resin extending out of the first groove, the first filling resin including an upper surface which protrudes outside of the patterned portion of the patterned glass between the inclined side surfaces of the upper guide adhesive layers, and filling the resin material in the lower filling space to define a second filling resin extending out of the second groove, the second filling resin including a lower surface which protrudes outside of the patterned portion of the patterned glass between the inclined side surfaces of the lower guide adhesive layers.

According to an embodiment of the invention, at least one of an upper surface of a first filling resin, and a lower surface of a second filling resin is outside of the pattern glass PG and includes inclined surfaces, thereby making it possible prevent buckling from occurring in adhesive layers which cover boundaries between the pattern glass PG and each of the first filling resin and the second filling resin during folding. Therefore, the surface quality of a display device DD may be improved.

In the above, description has been made with reference to embodiments of the invention, but those skilled in the art or those of ordinary skill in the relevant technical field may understand that various modifications and changes may be made to the invention within the scope not departing from the spirit and the technical scope of the invention described in the claims to be described later. In addition, the embodiments disclosed in the invention are not intended to limit the technical spirit of the invention, and all technical ideas within the scope of the following claims and their equivalents should be construed as being included in the scope of the invention.

What is claimed is:

1. A display device comprising:
a display panel which includes a display surface and is foldable at a folding region; and
a patterned glass on the display panel, the patterned glass including:
a first non-patterned portion, a patterned portion corresponding to the folding region, and a second non-patterned portion which are in order in a first direction, and
the patterned portion including:
an upper surface,
a lower surface which is opposite to the upper surface and closer to the display surface of the display panel than the upper surface,
a first groove recessed from the upper surface, and
a second groove recessed from the lower surface;
a first filling resin filling the first groove; and
a second filling resin filling the second groove,
wherein at least one of an upper surface of the first filling resin or a lower surface of the second filling resin protrudes outward from the pattern glass, and the protruding upper surface of the first filling resin, or the protruding lower surface of the second filling resin includes an inclined surface.

2. The display device of claim 1, wherein
the display panel which is folded with respect to a folding axis parallel to a second direction crossing the first direction includes portions of the display surface facing each other, and
the lower surface of the second filling resin protrudes outside of the patterned portion of the patterned glass.

3. The display device of claim 2, wherein the lower surface of the second filling resin comprises:
a first flat portion parallel to a plane defined by the first direction and the second direction; and
first inclined surfaces respectively extending from opposing ends of the first flat portion in the first direction.

4. The display device of claim 2, wherein a total width of the second filling resin in the first direction is smaller than a total width of the patterned portion of the patterned glass in the first direction.

5. The display device of claim 2, wherein a total width of the second filling resin in the first direction is the same as a total width of the patterned portion of the patterned glass in the first direction.

6. The display device of claim 2, further comprising a lower adhesive layer which is on the lower surface of the patterned glass and covers the second filling resin.

7. The display device of claim 6, wherein
the display panel which is folded at the folding region includes the lower surface of the patterned glass having a curvature and the lower surface of the second filling resin having a curvature, and
at a boundary between the lower surface of the patterned glass and the lower surface of the second filling resin, the curvature of the lower surface of the patterned glass is the same as the curvature of the lower surface of the second filling resin.

8. The display device of claim 2, wherein
the upper surface of the first filling resin protrudes beyond the upper surface of the pattern glass, and
the upper surface of the first filling resin comprises:
a second flat portion parallel to a plane defined by the first direction and the second direction, and
second inclined surfaces respectively extending from opposing ends of the second flat portion in the first direction.

9. The display device of claim 1, wherein
the display panel which is folded with respect to a folding axis parallel to a second direction crossing the first direction includes portions of the display surface facing away from each other, and
the upper surface of the first filling resin protrudes beyond the upper surface of the pattern glass.

10. The display device of claim 9, wherein the upper surface of the first filling resin comprises:
a second flat portion parallel to a plane defined by the first direction and the second direction; and
second inclined surfaces respectively extending from opposing ends of the second flat portion in the first direction.

11. The display device of claim 9, wherein a total width of the first filling resin in the first direction is smaller than a total width of the patterned portion in the first direction.

12. The display device of claim 9, further comprising an upper adhesive layer which is on the upper surface of the patterned glass and covers the first filling resin.

13. A method for providing a display device, the method comprising:
providing a patterned glass which is foldable together with a display panel, the patterned glass including:
a patterned portion corresponding to a folding region of the display panel and a non-patterned portion which is adjacent to the patterned portion in a first direction, and
each of the patterned portion and the non-patterned portion including an upper surface and a lower surface which is opposite to the upper surface and closer to the display panel than the upper surface;
providing guide adhesive layers on each of the upper surface and the lower surface of the non-patterned portion, the guide adhesive layers on a respective surface among the upper and lower surfaces including inclined side surfaces facing each other across the patterned portion and defining a filling space with the patterned portion;
filling the filling space with a resin material; and
providing the patterned glass having the filling space which is filled with the resin material, on the display panel.

14. The method of claim 13, wherein
the patterned portion of the patterned glass further includes a first groove recessed from the upper surface at the patterned portion and a second groove recessed from the lower surface at the patterned portion,
the guide adhesive layers comprise:
upper guide adhesive layers on the upper surface of the non-patterned portion and defining an upper filling space with the first groove, and
lower guide adhesive layers on the lower surface of the non-patterned portion and defining a lower filling space with the second groove, and the providing the resin material comprises:
filling the resin material in the upper filling space to define a first filling resin extending out of the first groove, the first filling resin including an upper surface which protrudes outside of the patterned portion of the patterned glass between the inclined side surfaces of the upper guide adhesive layers, and
filling the resin material in the lower filling space to define a second filling resin extending out of the second groove, the second filling resin including a lower surface which protrudes outside of the patterned portion of the patterned glass between the inclined side surfaces of the lower guide adhesive layers.

15. The method of claim 14, wherein the lower surface of the second filling resin comprises:
a first flat portion; and
first inclined surfaces respectively extending from opposing ends of the first flat portion in the first direction.

16. The method of claim 15, wherein the upper surface of the first filling resin comprises:
a second flat portion; and
second inclined surfaces extending from opposing sides of the second flat portion in the first direction.

17. The method of claim 15, wherein the providing of the patterned glass on the display panel comprises:
providing a lower adhesive layer which is between the patterned glass and the display panel and covers the second filling resin; and
providing an upper adhesive layer which is on the upper surface of the patterned glass and covers the first filling resin.

18. The method of claim 17, wherein
the patterned glass further includes a first non-patterned portion, the patterned portion and a second non-patterned portion in order in the first direction, and
the display panel which is folded at the folding region with respect to a folding axis parallel to a second direction crossing the first direction includes:
the first non-patterned portion and the second non-patterned portion facing each other,
the lower surface of the patterned glass having a curvature and the lower surface of the second filling resin having a curvature, and
at a boundary between the lower surface of the patterned glass and the lower surface of the second filling resin, the curvature of the lower surface of the patterned glass is the same as the curvature of the lower surface of the second filling resin.

19. The method of claim 14, wherein a total width of the first filling resin or the second filling resin in the first direction is smaller than a total width of the patterned portion in the first direction.

20. The method of claim 14, wherein a total width of the first filling resin or the second filling resin in the first direction is the same as a total width of the patterned portion in the first direction.

21. A electronic device comprising:
a display device; and
a housing disposed under the display device and coupled to the display device,
a display panel which includes a display surface and is foldable at a folding region; and
a patterned glass on the display panel, the patterned glass including:
a first non-patterned portion, a patterned portion corresponding to the folding region, and a second non-patterned portion which are in order in a first direction, and
the patterned portion including:
an upper surface,
a lower surface which is opposite to the upper surface and closer to the display surface of the display panel than the upper surface,
a first groove recessed from the upper surface, and
a second groove recessed from the lower surface;
a first filling resin filling the first groove; and
a second filling resin filling the second groove,
wherein at least one of an upper surface of the first filling resin or a lower surface of the second filling resin protrudes outward from the pattern glass, and the protruding upper surface of the first filling resin, or the protruding lower surface of the second filling resin includes an inclined surface.
